(19) United States
(12) Patent Application Publication
(10) Pub. No.: US 2023/0282481 A1
(43) Pub. Date: Sep. 7, 2023

(54) METHOD FOR MANUFACTURING GAN-BASED POWER DEVICE AND GANBASED POWER DEVICE MANUFACTURED THEREBY

(71) Applicant: KOREA ATOMIC ENERGY RESEARCH INSTITUTE, Daejeon (KR)

(72) Inventors: Dong Seok KIM, Daegu (KR); Young Jun YOON, Daegu (KR); Jae Sang LEE, Daegu (KR)

(21) Appl. No.: 18/198,024

(22) Filed: May 16, 2023

Related U.S. Application Data
(63) Continuation of application No. PCT/KR2021/017308, filed on Nov. 23, 2021.

(30) Foreign Application Priority Data
Nov. 24, 2020 (KR) 10-2020-0159070

(51) Int. Cl. H01L 21/265; H01L 29/778

(52) U.S. Cl. CPC H01L 21/26553; H01L 29/7786

(57) ABSTRACT

The present invention relates to: a method for manufacturing a GaN-based power device, the method comprising a step of irradiating particle beams onto a silicon substrate of a GaN-based power device, in which the silicon substrate is included; and a GaN-based power device manufactured by the method for manufacturing a GaN-based power device.

### CROSS REFERENCE TO RELATED APPLICATION

This application is a continuation of International Patent Application No. PCT/KR2021/017308, filed on Nov. 23, 2021, which is based on and claims priority to Korean Patent Application No. 10-2020-0159070, filed Nov. 24, 2020, with the Korean Intellectual Property Office, the disclosure of which are incorporated herein by reference in their entireties.

### TECHNICAL FIELD

The present invention relates to a method for manufacturing GaN-based power device and a GaN-based power device manufactured thereby.

### BACKGROUND ART

Gallium nitride(GaN)-based power devices have a wide bandgap energy (Eg=3.4 eV) and a high breakdown electric field (3 MV/cm), and have the property of forming a two-dimensional electron gas(2DEG) with high electron concentration. Thus, GaN-based power devices are in the limelight as a next-generation power semiconductor along with SiC-based power devices.

When manufacturing such a GaN-based power device, there is a difficulty in manufacturing a GaN homogeneous substrate. Thus, a GaN-based epitaxy thin film is grown on a sapphire(Al₂O₃) substrate, a silicon substrate, or a silicon carbide substrate(SiC), and a power device is manufactured using the grown thin film. Here, when using a silicon substrate rather than using a sapphire substrate or silicon carbide substrate, it is possible to use a large-diameter substrate of 8 inches or more, so it is quite economical in terms of price compared to other power semiconductors.

However, due to the difference in lattice constant and thermal expansion coefficient between a GaN-based thin film and a silicon substrate, an MN thin film is generally used as a buffer layer for growing a high-quality thin film, but in this case, a high-concentration conductive layer is formed between an interface between the AIN thin film and the silicon substrate. This conductive layer has been found to be a high-concentration electron layer (an inversion electron channel) formed by the energy bandgap difference between the MN thin film and the silicon substrate and the electrons supplied from the silicon substrate (Reference 1).

Due to this conductive layer, when a high voltage of several hundred volts or more is applied to a power device, the power device is damaged due to vertical leakage current caused by the conductive layer, so there is a limit to improving a breakdown voltage, one of the important characteristics of the power device.

As a method for increasing the breakdown voltage of a GaN-based power device (i.e., a method for reducing leakage current), there is a method for increasing a space between a gate and a drain, but as the space between the gate and the drain increases, the channel resistance of the power device increases correspondingly, and thus the operating characteristics of the power device may degrade (trade-off relationship). In addition, there is a method of reducing the vertical leakage current by increasing the resistance or thickness of the GaN thin film below the channel of the power device. However, since there is a limit to increasing the resistance or thickness of the GaN thin film, it is less effective than the method of increasing the space between the gate and the drain, and there is still a problem of increasing the vertical leakage current due to the conductive layer.

Alternatively, in order to reduce the vertical leakage current, a method for using a high-resistance silicon substrate or removing the silicon substrate after device manufacturing is completed has been previously proposed. However, it has been reported that high-resistance silicon substrates are very expensive compared to general substrates, and cause a strong charge trapping effect to degrade power device characteristics (Non-Patent Document 1).

The method for removing the silicon substrate has a problem in that an additionally complicated subsequent process is required.

### DOCUMENT OF RELATED ART

### Non-Patent Document

(Non-Patent Document 1) M. Borga, et al., “Impact of Substrate Resistivity on the Vertical Leakage, Breakdown, and Trapping in GaN-on-Si E-Mode HEMTs,” IEEE Trans. Electron Devices, Vol. 65, pp. 2765-2770, 2018.

### DISCLOSURE

### Technical Problem

The present invention is to solve the above problems, and is to improve breakdown voltage characteristics by irradiating a particle beam onto a silicon substrate of a GaN-based power device using a particle beam irradiation technology to remove the cause of leakage current without damaging the thin film of the GaN-based power device.

### Technical Solution

One embodiment of the present invention provides a method for manufacturing a GaN-based power device comprising the step of irradiating a particle beam onto a silicon substrate of a GaN-based power device including a silicon substrate.

Another embodiment of the present invention provides a GaN-based power device manufactured by the method for manufacturing a GaN-based power device.

### Advantageous Effect

According to the method for manufacturing a GaN-based power device of the present invention, damage to a thin film of a GaN-based power device can be minimized by irradiating a particle beam onto a silicon substrate, thereby preventing degradation of characteristics of the device. In addition, as the particle ions are intensively distributed at an interface between the MN thin film and silicon substrate of the GaN-based power device by the incident particle beam, resistance is increased to eliminate the cause of leakage current, thereby improving breakdown voltage characteristics.

Furthermore, the method for manufacturing a GaN-based power device of the present invention as described above has high utilization value in that it is a technology that can be applied in an end process after the manufacturing of the GaN-based power device is completed, and since the particle beam can irradiate a large area, there is an advantage in that a large amount of power devices can be processed simultaneously.

In addition, it is advantageous in terms of economy because breakdown voltage characteristics of the GaN-based power device can be improved through particle beam irradiation in a simple process without an additional and complicated subsequent process for removing the silicon substrate as in the prior art.

### DESCRIPTION OF DRAWINGS

FIG. 1 is a diagram schematically illustrating a method for manufacturing a GaN-based power device according to an embodiment of the present invention.

FIG. 2 is a diagram illustrating a distribution of protons implanted into the GaN-based power device A of Example 1 according to Experimental Example 1 of the present invention.

FIG. 3 is a diagram illustrating a distribution of protons implanted into the GaN-based power device B of Example 2 according to Experimental Example 1 of the present invention.

FIG. 4 is a diagram illustrating a result of evaluating an on-current characteristic of the GaN-based power device C of Comparative Example 1 according to Experimental Example 2 of the present invention.

FIG. 5 is a diagram illustrating a result of measuring a breakdown voltage of the GaN-based power device A of Example 1 before and after proton beam irradiation according to Experimental Example 3 of the present invention.

### MODE FOR INVENTION

The present invention may be modified in various forms, and have several embodiments. specific embodiments thereof will be illustrated in the drawings and described in detail in the detailed description. However, it is to be understood that the embodiments are not intended to limit the invention but to include all modifications, equivalents and substitutions falling within the spirit and scope of the invention.

The terms used in the specification are used to merely describe specific embodiments, but are not intended to limit the invention. An expression of a singular number includes an expression of the plural number unless the context clearly dictates otherwise.

In the specification, the expression “— on” may mean that members are directly joined and attached, or may mean that members are positioned adjacent to each other.

Thus, configurations illustrated in the embodiments described in the specification are merely most preferable embodiments but do not represent all of the technical spirit of the present invention, and thus, there may be various equivalents and modifications that can replace the configurations at the time of filing this application.

Hereinafter, the present invention will be described in detail.

The present invention provides a method for manufacturing a GaN-based power device.

The method for manufacturing a GaN-based power device may include the step of irradiating a particle beam onto a silicon substrate of a GaN-based power device including the silicon substrate.

The power device collectively refers to electronic components using electron conduction in a solid, and as a typical example, there is a power semiconductor that performs control processing such as DC/AC conversion, voltage, and frequency change in order to utilize electrical energy. In addition to this, the power device may refer to, for example, a rectifier diode, a thyristor, a transistor, and the like, but is not limited thereto.

The GaN-based power device refers to a power device including a GaN-based material. For example, the GaN-based power device may be a power device that includes a thin film having a GaN-based material. Specifically, the GaN-based material may have GaN, AlGaN or the like, but is not limited thereto.

The gallium nitride(GaN) is a material with a wide band gap(WBG) that is stronger at high pressure and high temperature than a conventional silicon(Si). In the case of using a AlGaN/GaN-based heterojunction structure, a 2-dimensional electron gas(2DEG) layer with high electron concentration and high electron mobility is used, and energy loss is reduced by excellent current characteristics and fast signal conversion speed, so that power consumption can be saved. Therefore, the GaN material is suitable for a high-power semiconductor device.

The GaN-based power device may include a silicon substrate. The GaN-based power device may include an epitaxy thin film having a GaN-based material on a silicon substrate.

The GaN-based power device may be manufactured using a known thin film deposition growth technique. For example, the GaN-based power device may be manufactured by growing an GaN-based thin film on the silicon substrate by using a technology such as molecular beam epitaxy(MBE), metal organic chemical vapor deposition(MOCVD), or hydride vapor phase epitaxy(HVPE), but is not limited thereto. In particular, due to the hexagonal wurtzite crystalline structure and growth direction characteristics of gallium nitride(GaN), the use of metal organic chemical vapor deposition(MOCVD) is advantageous in that a thin film of superior quality can be obtained in depositing the GaN-based material, and deposition may be performed on multiple substrates at the same time, but the present invention is not limited thereto.

The metal organic chemical vapor deposition(MOCVD) as described above is a method of supplying an organometallic compound (organometal raw material gas) into a reactor and thermally decomposing it on a heated substrate to grow a compound crystal. There is an advantage in that the thickness of the heterojunction can be adjusted to a nano level by controlling the flow rate of the highly purified organometallic compound and the temperature and pressure of the reactor.

For example, the GaN-based power device may include a structure in which a silicon substrate, an AlN-based thin film, a first AlGaN-based thin film, a first GaN-based thin film, a second GaN-based thin film, and a second AlGaN-based thin film are sequentially stacked.

Specifically, the AlN-based thin film may include an AlN-based nucleation layer, the first GaN-based thin film may include a GaN-based buffer layer, the second GaN-based thin film may include a GaN-based channel layer, the first AlGaN-based thin film may include an AlGaN-based transition layer, and the second AlGaN-based thin film may include an AlGaN-based barrier layer.

The GaN-based buffer layer refers to a layer with high resistance, and may contain a myriad of defects generated during growth, or may be intentionally implemented by doping ions such as iron(Fe) and carbon(C) during thin film growth.

The GaN-based channel layer is a high-quality thin film with fewer defects compared to the GaN-based buffer layer, and may refer to a region where a 2DEG layer is formed in an AlGaN/GaN heterojunction structure.

The AlGaN-based transition layer is a layer for minimizing stress caused by a difference in lattice mismatch and thermal expansion coefficient between the AlN-based thin film and the first GaN-based thin film (for example, a GaN-based buffer layer). The AlGaN-based transition layer may include an AlGaN-based transition layer having an intermediate lattice constant and thermal expansion coefficient, and may be composed of one or several layers, and may have a thickness of several tens of nm to several μm.

The AlGaN-based barrier layer is a layer for forming a 2DEG layer through an AlGaN/GaN heterojunction, and has a thickness of about several tens of nm.

That is, the GaN-based power device may include a structure in which a silicon substrate, an AlN-based nucleation layer, an AlGaN-based transition layer, a GaN-based buffer layer, a GaN-based channel layer, and an AlGaN-based barrier layer are sequentially stacked.

The GaN-based power device may further include a surface passivation layer on a portion of the second AlGaN-based thin film. The surface passivation layer serves to block the inflow of moisture from the outside or the absorption or movement of harmful ions, and may also serve to block an increase in leakage current.

The surface passivation layer may be, for example, an insulating layer material including SiO₂, SiNₓ (e.g., Si₃N₄), Al₂O₃, Ga₂O₃, HfO₂, or a mixture thereof, but is not limited thereto.

The GaN-based power device may further include at least one of a source electrode, a drain electrode, and a gate electrode on a portion of the second AlGaN-based thin film.

That is, at least one of a source, drain, and gate electrode may be formed on the second AlGaN-based thin film, and the above-described surface passivation layer may be formed on a portion where the source, drain, or gate electrode is not formed.

In this case, a space between the gate and the drain may be 5 to 30 μm, specifically 10 to 30 μm. If the space between the gate and the drain satisfies the above range, the breakdown voltage of the GaN-based power device may be increased. The longer the space between the gate and the drain exceeds 30 μm, the higher the breakdown voltage and the higher the on-resistance, so if the above range is satisfied, both the breakdown voltage and the on-resistance characteristics that are required by the power device of the present invention can be satisfied.

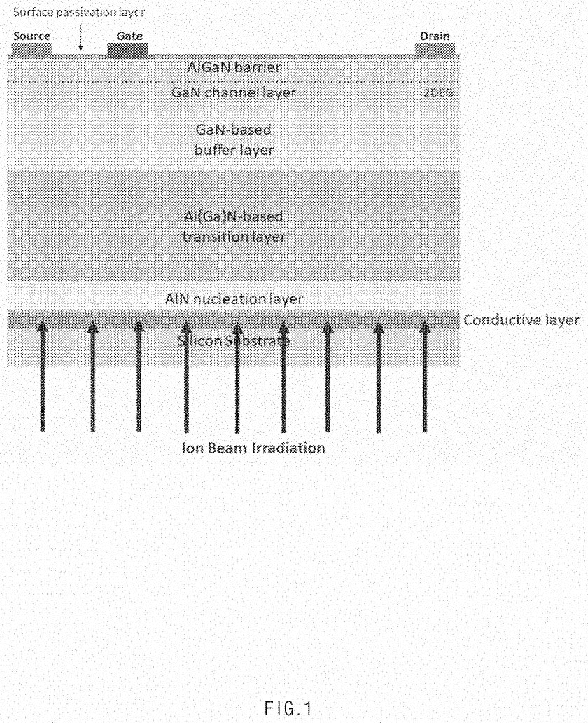

As illustrated in FIG. 1, the method for manufacturing a GaN-based power device of the present invention may be to irradiate the particle beam onto the silicon substrate.

When the particle beam is irradiated onto the source, drain, and gate electrode, or surface passivation layer, or second AlGaN-based thin film of the GaN-based power device, the particle ions derived from the particle beam incident into the GaN-based power device cause defects in the GaN-based thin film or AlGaN-based thin film inside the power device, or cause a defect in the 2DEG, or a displacement damage effect occurs, so that the device characteristics of the GaN-based power device may be degraded.

Therefore, as the particle beam is irradiated onto the silicon substrate of the GaN-based power device, particle ions can be intensively implanted and/or distributed in the interface region between the AlN-based thin film and the silicon substrate without thin film damage (defect) or 2DEG defect. Therefore, the breakdown voltage can be improved by removing the conductive layer to block the cause of leakage current.

The particle beam may include at least one selected from the group consisting of a proton beam, a nitrogen(N) ion beam, an iron(Fe) ion beam, a carbon(C) ion beam, a helium(He) ion beam, and an argon(Ar) ion beam.

Specifically, the particle beam may include a proton beam. In the case of using the proton beam, due to the nature of the ion species (smallest and lightest), there are few defects during the movement of the ion beam, and it has the advantage that defects can be generated at a desired location (bragg peak characteristic), so that compared to other types of ion beams, the damage to other regions of the device can be minimized.

The particle beam is in the form of a charged particle beam made of particle ions, and is also referred to as an ion beam or an electron beam. This particle beam irradiation technique uses a phenomenon in which kinetic energy of particle (ions) having high energy is transmitted to the surface of a power device and converted into kinetic energy. The particle ions incident on the surface of the electronic device irradiated with the particle beam cause a collision cascade of atoms of the power device, and the properties of the material may be modified by elastic or inelastic collision. In this case, if the particle beam energy is higher than the binding energy of surface atoms, a sputtering phenomenon occurs in which particles break atomic bonds on the surface and emit the atoms to the outside. Conversely, if the particle beam energy is lower than the binding energy of surface atoms, ion implantation occurs, in which the particle collides with the surface atoms in a chain and the particles are remained.

Immediately after the particle implantation, a defect occurs in the crystal structure due to collision, and in order for the implanted particles to function as dopants, the particles must be positioned at substitution sites in the crystal structure, but due to defects, the particles do not have the original crystal structure and are not electrically activated. Therefore, it is necessary to recrystallize the defective crystal structure through an annealing process to restore it to a normal state, and to move the implanted particles to a substitution site in the crystal structure to act as dopants and electrically activate them. The annealing method includes furnace annealing, rapid thermal annealing, laser annealing, e-beam annealing, or the like.

The step of irradiating of the particle beam may include implanting particle ions into an interface region between the silicon substrate and the AlN-based thin film by irradiating the particle beam. As the resistance increases due to the particle ions implanted into the interface region between the silicon substrate and the AlN-based thin film as described above, the high-concentration conductive layer is removed, thereby improving the breakdown voltage of the GaN-based power device.

The energy of the particle beam may be 5 to 15 MeV. Specifically, the energy of the particle beam may be 5 to 12 MeV, 8 to 15 MeV, or 9 to 12 MeV.

The GaN-based thin film (the AlN-based thin film, the first AlGaN-based thin film, the first GaN-based thin film, the second GaN-based thin film, and/or the second AlGaN-based thin film) grown on the silicon substrate is very thin (about several μm) compared to the silicon substrate. Thus, if the above particle beam energy is not satisfied, the particle beam irradiated onto the back side (i.e., the silicon substrate) passes through the 2DEG layer that determines the performance of the electronic device so that the 2DEG layer is damaged and a performance degradation may be occurred. Alternatively, the above problem may occur even when the particle beam is irradiated onto a front surface (i.e., the electrode, the surface passivation layer, or the second AlGaN-based thin film) instead of the silicon substrate. Therefore, when irradiating a particle beam onto the silicon substrate, it is necessary to irradiate the particle beam with optimal energy in consideration of the thickness of the silicon substrate.

The silicon substrate may have a thickness of 500 to 1,500 μm. Specifically, the silicon substrate may have a thickness of 600 to 1,200 μm, 600 to 1,000 μm, or 650 to 1,000 μm.

Specifically, if the thickness of the silicon substrate used in the GaN-based power device is 500 μm or more and less than 800 μm, the energy of the particle beam may be 5 MeV or more and less than 10 MeV. Also, if the thickness of the silicon substrate used in the GaN-based power device is 800 μm or more and 1,500 μm or less, the energy of the particle beam may be 10 MeV or more and 15 MeV or less.

If the thickness of the silicon substrate satisfies the above range and the energy of the particle beam satisfies the above range, particle implantation and/or distribution at the interface between the AlN-based thin film and the silicon substrate can be optimized while minimizing damage to the thin film in the GaN-based power device. Therefore, it is effective in improving the breakdown voltage of the GaN-based power device as the conductive layer can be easily removed.

In the method for manufacturing a GaN-based power device, the silicon substrate may not be removed after irradiation of the particle beam. Conventionally, there has been a method for removing the silicon substrate from a manufactured power device in order to reduce the vertical leakage current, but this method additionally requires a very complicated subsequent process. However, the method for manufacturing a GaN-based power device of the present invention can have the effect of blocking the cause of leakage current and improving the breakdown voltage by irradiating the particle beam onto the silicon substrate of the power device. Therefore, there is an advantage in that a process of removing the silicon substrate is not required.

An average particle implantation amount of the particle beam implanted into the GaN-based power device may be 1×10¹³ to 1×10¹⁶ ions/cm³. If the average particle implantation amount of the particle beam satisfies the above range, a sufficient displacement damage effect is applied to the interface layer between the silicon substrate and the AlN-based thin film, thereby increasing resistance and increasing breakdown voltage.

The average particle implantation amount may be measured through the amount of beam current delivered to the device, and the beam current may be measured using a Faraday cup or the like.

Another embodiment of the present invention provides a GaN-based power device manufactured according to the method for manufacturing a GaN-based power device described above.

The GaN-based power device may have minimized damage to the thin film of the GaN-based power device by irradiating the particle beam onto the silicon substrate, and have an improved breakdown voltage characteristic by increasing resistance and removing the cause of leakage current as the ions are intensively distributed on an interface between the AlN thin film and silicon substrate of the GaN-based power device by incident and/or implanted particle beams.

Hereinafter, the present invention will be described in more detail with reference to preferred embodiments.

However, these examples are intended to explain the present invention in more detail, and the scope of the present invention is not limited thereby.

### Example 1

A device in which a 6-inch silicon substrate (thickness 650 μm)/an AlN nucleation layer/an AlGaN transition layer/a GaN buffer layer/a GaN channel layer/an AlGaN barrier layer were sequentially stacked and a source, a drain, a gate, and a surface passivation layer were formed on the AlGaN barrier layer was manufactured. Then, a 9 MeV proton beam was irradiated onto the silicon substrate of the device to manufacture a GaN-based power semiconductor device of the present invention.

### Example 2

Except that an 8-inch silicon substrate (thickness of 1,000 μm) was used instead of the 6-inch silicon substrate (thickness of 650 μm) of Example 1 and a 12 MeV proton beam was irradiated instead of the 9 MeV proton beam of Example 1, a GaN-based power semiconductor device B was manufactured in the same manner as in Example 1 described above.

### Comparative Example 1

Instead of irradiating the proton beam onto the silicon substrate of the device of Example 1, the proton beam of 5 MeV was irradiated onto the front surface (i.e., the surface passivation layer or the electrode) to manufacture a GaN-based power semiconductor device C in the same manner as in Example 1.

### Experimental Example 1

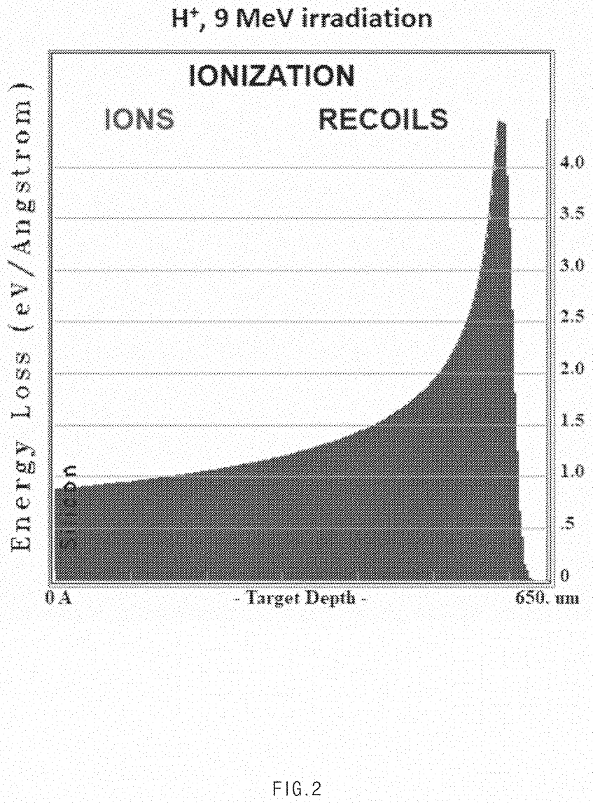

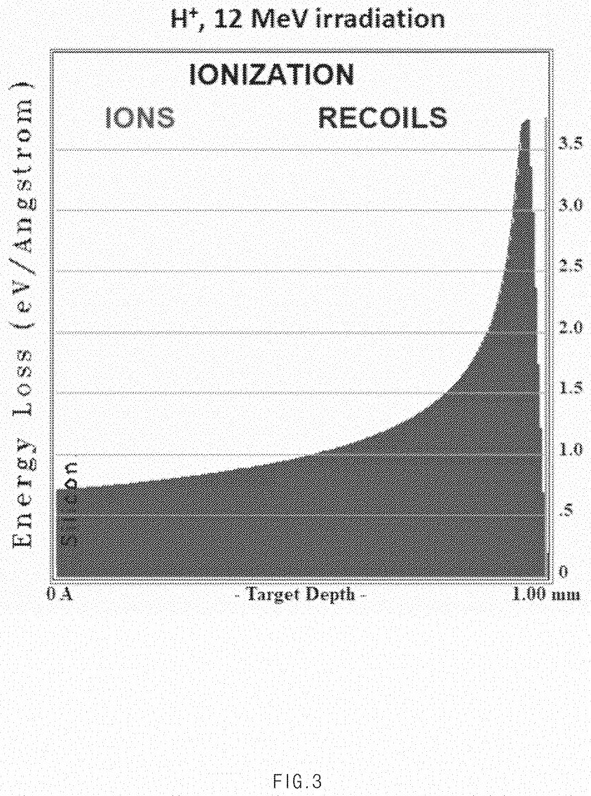

The distribution of the proton beam incident on the silicon substrate of the GaN-based power device A manufactured in Example 1 was determined using the Stopping and Range of Ions in Matter(SRIM) simulation tool and the result was shown in FIG. 2. The distribution of the proton beam incident on the silicon substrate of the GaN-based power device B manufactured in Example 2 was determined using the same SRIM simulation tool and the result was shown in FIG. 3.

### Experimental Example 2

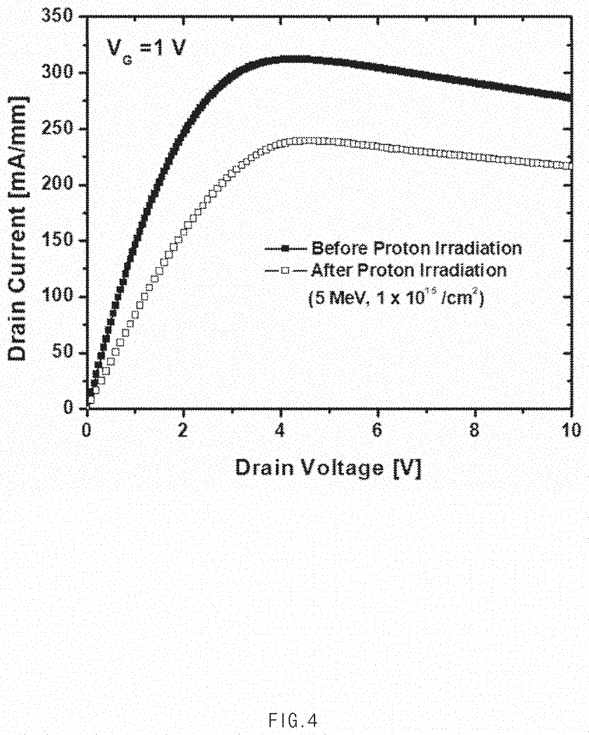

The on-current (drain current) characteristic of the GaN-based power device C manufactured in Comparative Example 1 was evaluated and the result was shown in FIG. 4.

According to FIG. 4, when the proton beam was irradiated onto the electrode or the surface passivation layer instead of the silicon substrate as in Comparative Example 1, it was confirmed that compared to before irradiation of the proton beam, the GaN-based thin film was damaged and the performance of the power device was degraded.

Specifically, it was confirmed that the 2DEG layer, which determined the performance of the power device, was damaged and the on-current (drain current) characteristic was reduced after proton beam irradiation.

### Experimental Example 3

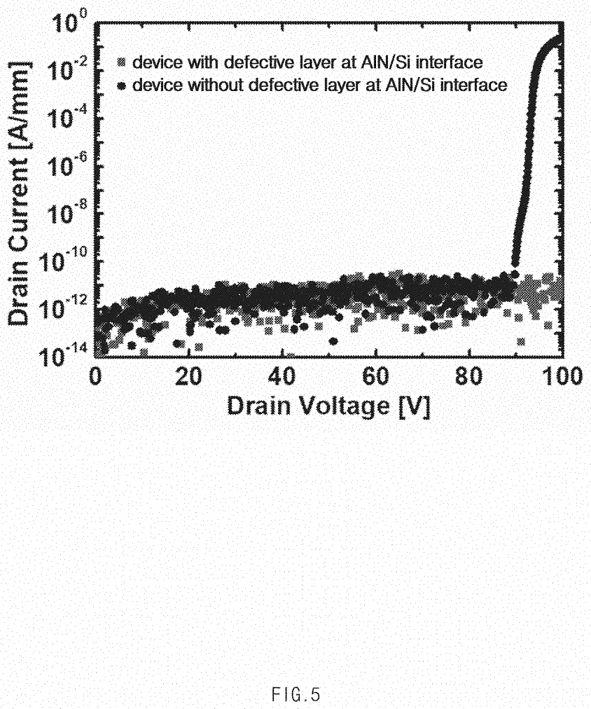

For the GaN-based power semiconductor device A manufactured in Example 1 and the device not irradiated with a proton beam in Example 1, the breakdown voltage according to vertical leakage current was measured through 3-dimensional technology computer-aided design(TCAD) device simulation and the result was shown in FIG. 5.

According to FIG. 5, it was confirmed that the GaN-based power semiconductor device A (a device with a defect layer at the AlN/Si interface) manufactured in Example 1 has considerably low current level (drain current) even at a high voltage (100 V) compared to a device to which the proton beam was not irradiated (a device without a defect layer at the AlN/Si interface). This means that the leakage current is relatively low even at a high voltage greater than 100 V, which in turn means that the breakdown voltage is relatively high. In comparison, it can be confirmed that the leakage current of the device without the defect layer increases rapidly at 90 V, which means that the breakdown voltage is low.

1. A method for manufacturing a GaN-based power device, comprising the step of irradiating a particle beam onto a silicon substrate of a GaN-based power device including the silicon substrate.

2. The method of claim 1, wherein the GaN-based power device includes a structure in which a silicon substrate, an AlN-based thin film, a first AlGaN-based thin film, a first GaN-based thin film, a second GaN-based thin film, and a second AlGaN-based thin film are sequentially stacked.

3. The method of claim 2, wherein the AlN-based thin film includes an AlN-based nucleation layer,
the first GaN-based thin film includes a GaN-based buffer layer,
the second GaN-based thin film includes a GaN-based channel layer,
the first AlGaN-based thin film includes an AlGaN-based transition layer, and
the second AlGaN-based thin film includes an AlGaN-based barrier layer.

4. The method of claim 1, wherein the particle beam includes at least one selected from the group consisting of a proton beam, a nitrogen(N) ion beam, an iron(Fe) ion beam, a carbon(C) ion beam, a helium(He) ion beam, and an argon(Ar) ion beam.

5. The method of claim 1, wherein the particle beam includes a proton beam.

6. The method of claim 1, wherein an energy of the particle beam is 5 to 15 MeV.

7. The method of claim 1, wherein the silicon substrate has a thickness of 500 to 1,500 μm.

8. The method of claim 2, wherein the step of irradiating the particle beam includes implanting a particle ion into an interface region between the silicon substrate and the AlN-based thin film by irradiating the particle beam.

9. The method of claim 1, wherein the silicon substrate is not removed after irradiating the particle beam.

10. A GaN-based power device which is manufactured by the method for manufacturing a GaN-based power device of claim 1.
